(19) United States
(12) Patent Application Publication
(10) Pub. No.: US 2025/0141395 A1
(43) Pub. Date: May 1, 2025

(54) BACKSHEETS FOR PHOTOVOLTAIC MODULES

(71) Applicant: GAF Energy LLC, Parsippany, NJ (US)

(72) Inventors: Emma Dohner, San Francisco, CA (US); William Sirski, San Jose, NJ (US)

(21) Appl. No.: 18/925,844

(22) Filed: Oct. 24, 2024

Related U.S. Application Data
(60) Provisional application No. 63/593,374, filed on Oct. 26, 2023.

(51) Int. Cl. H02S 20/23; H02S 20/26

(52) U.S. Cl. CPC H02S 20/23; H02S 20/26

(57) ABSTRACT

A roofing system, including a roof deck and a plurality of photovoltaic modules installed on the roof deck. Each of the plurality of photovoltaic modules includes at least one solar cell, an encapsulant encapsulating the at least one solar cell, and a backsheet below the encapsulant. The backsheet includes a first layer, where the first layer contacts the roof deck, and where the first layer comprises a plurality of cavities or a plurality of ribs.

### CROSS-REFERENCE TO RELATED APPLICATION

This application is a Section 111(a) application relating to and claiming the benefit of commonly owned, co-pending U.S. Provisional Patent Application Ser. No. 63/593,374, filed Oct. 26, 2023, entitled “PHOTOVOLTAIC MODULE AND ROOFING SYSTEM INCLUDING PHOTOVOLTAIC MODULE,” the contents of which is incorporated herein by reference in its entirety.

### FIELD

The present disclosure relates to photovoltaic modules, and more particularly, backsheets for photovoltaic modules and roofing modules.

### BACKGROUND

In a roofing system, an installer installs a plurality of roofing materials on a roof deck. The plurality of roofing materials may include a plurality of photovoltaic modules installed on the roof deck, as well as a plurality of non-photovoltaic modules.

### SUMMARY

The Claims, rather than the Summary, define covered embodiments of the present disclosure. The Summary is a high-level overview of various aspects of the disclosure, and introduces concepts that are further described in the Detailed Description below. The Summary is not intended to identify key or essential features of the claimed subject matter, and also is not intended to be used in isolation to determine the scope of the claimed subject matter. Instead, the claimed subject matter should be understood by reference to appropriate portions of the Specification and drawings, as well as to each claim.

In some embodiments, a roofing system includes a roof deck; and a plurality of photovoltaic modules installed on the roof deck, wherein each of the plurality of photovoltaic modules includes at least one solar cell, an encapsulant encapsulating the at least one solar cell, and a backsheet, wherein the backsheet is below the encapsulant, wherein the backsheet comprises a first layer, and wherein the first layer comprises a plurality of cavities.

In some embodiments, the plurality of cavities comprises at least one closed cavity. In some embodiments, the plurality of cavities comprises at least one open cavity. In some embodiments, each of the plurality of photovoltaic modules further comprises a filler material in at least one cavity of the plurality of cavities. In some embodiments, the filler material comprises a fire-retardant material. In some embodiments, the fire-retardant material comprises a liquid. In some embodiments, the filler material comprises a phase-change material. In some embodiments, the phase-change material comprises hydrated salts. In some embodiments, the hydrated salts comprises calcium or sodium. In some embodiments, the filler material comprises a gas. In some embodiments, the gas comprises air. In some embodiments, the gas comprises an inert gas. In some embodiments, the plurality of cavities comprises at least two channels extending between opposite ends of the first layer. In some embodiments, the at least two channels extend along a major dimension of the photovoltaic module.

In some embodiments, a roofing system includes a roof deck; and a plurality of photovoltaic modules installed above the roof deck, wherein each of the plurality of photovoltaic modules includes at least one solar cell, an encapsulant encapsulating the at least one solar cell, and a backsheet, wherein the backsheet is below the encapsulant, wherein the backsheet comprises a first layer, and wherein the first layer comprises a plurality of ribs, and wherein each of the ribs extend between opposite ends of the first layer.

In some embodiments, the plurality of ribs comprises at least two ribs. In some embodiments, the plurality of ribs extends along a major dimension of the photovoltaic module.

In some embodiments, a photovoltaic module includes at least one solar cell; an encapsulant encapsulating the at least one solar cell; and a backsheet, wherein the backsheet is below the encapsulant, wherein the backsheet comprises a first layer, and wherein the first layer comprises a plurality of cavities.

In some embodiments, the plurality of cavities comprises at least one closed cavity. In some embodiments, In some embodiments, the plurality of cavities comprises at least one open cavity.

### BRIEF DESCRIPTION OF THE DRAWINGS

This section refers to the drawings that form a part of this disclosure, and which illustrate some of the embodiments of structure, materials, and/or methods of the present disclosure described herein.

FIG. 1 is a schematic, top view of a partial installation of a roofing system, in accordance with some embodiments.

FIG. 2 is a schematic, cross-sectional view of the backsheet of one of the photovoltaic modules of the roofing system, taken along section line A-A and looking in the direction of the arrows in FIG. 1, in accordance with some embodiments.

FIG. 3 is a schematic, cross-sectional view of the backsheet of one of the photovoltaic modules of the roofing system, taken along section line A-A and looking in the direction of the arrows in FIG. 1, in accordance with some embodiments.

FIG. 4 is a schematic, cross-sectional view of the backsheet of one of the photovoltaic modules of the roofing system, taken along section line A-A and looking in the direction of the arrows in FIG. 1, in accordance with some embodiments.

FIGS. 5A through 5C are schematic, cross-sectional views of some embodiments of backsheets of photovoltaic modules.

### DETAILED DESCRIPTION

In addition to the benefits and improvements that the Specification discloses, other objects and advantages that the Specification provides will become apparent from the following description taken in conjunction with the accompanying figures. Although the description discloses and describes detailed embodiments of the present disclosure, the disclosed embodiments are merely illustrative of the disclosure that may be embodied in various forms. In addition, each of the examples given regarding the various embodiments of the disclosure are intended to be illustrative, and not restrictive.

As used herein, a “steep slope” roof or roof deck is a roof or roof deck having a pitch of Y/X, where Y and X are in a ratio of 4:12 to 20:12, where Y corresponds to the “rise” of the roof or roof deck, and where X corresponds to the “run” of the roof or roof deck.

As used herein, a “sloped” roof or roof deck includes a roof or roof deck with a pitch that is less than that of a steep slope roof or roof deck, but which is not a flat roof or roof deck.

In some embodiments, the present disclosure provides a photovoltaic module. In some embodiments, the photovoltaic module includes a structure, composition, component, and/or function similar to those of one or more embodiments of the photovoltaic modules and shingles disclosed, shown, and/or described in any or all of: U.S. application Ser. No. 17/831,307, filed Jun. 2, 2022, titled “Roofing Module System,” and published under U.S. Patent Application Publication No. 2022-0393637 on Dec. 8, 2022, owned by GAF Energy LLC; U.S. application Ser. No. 18/169,718, filed Feb. 15, 2023, titled “Roofing Module System,” and published under U.S. Patent Application Publication No. 2023-0203815 on Jun. 29, 2023, owned by GAF Energy LLC; PCT International Patent Publication No. WO 2022/051593, Application No. PCT/US2021/049017, published Mar. 10, 2022, titled “Building Integrated Photovoltaic System,” owned by GAF Energy LLC; and/or U.S. Pat. No. 11,251,744 to Bunea et al., issued Feb. 15, 2022, titled “Photovoltaic Shingles and Methods of Installing Same,” owned by GAF Energy LLC; and “U.S. Pat. No. 11,870,227, issued Jan. 9, 2024, entitled “Building Integrated Photovoltaic System,” owned by GAF Energy LLC, the disclosures of each of which are incorporated by reference herein in their entireties, with certain different and/or additional features as described herein.

In some embodiments, the present disclosure provides a roofing system including at least one photovoltaic module. In some embodiments, the at least one photovoltaic module is installed on (e.g., directly on, with no intervening layer therebetween; or with one or more intervening layers, such as but not limited to an underlayment, therebetween) a roof deck.

In some embodiments, the roofing system includes at least one roofing material other than a photovoltaic module which is installed on the roof deck. In some embodiments, the roofing material is a non-photovoltaic module. In some embodiments, the roofing material is a roofing shingle. In some embodiments, the roofing material is a cuttable roofing module. In some embodiments, the roofing material is a nailable roofing module or roofing shingle. In some embodiments, the roofing material includes a structure, composition, component, and/or function similar to those of one or more embodiments of roofing materials disclosed, shown, and/or described in either or both of U.S. application Ser. No. 17/831,307, filed Jun. 2, 2022, titled “Roofing Module System,” and published under U.S. Patent Application Publication No. 2022-0393637 on Dec. 8, 2022, owned by GAF Energy LLC; and/or U.S. application Ser. No. 18/169,718, filed Feb. 15, 2023, titled “Roofing Module System,” and published under U.S. Patent Application Publication No. 2023-0203815 on Jun. 29, 2023, owned by GAF Energy LLC; and/or U.S. application Ser. No. 18/352,894, filed Jul. 14, 2023, titled “Solar Roofing System with Fiber Composite Roofing Shingles,” and published under U.S. Patent Application Publication No. 2024-0018781 on Jan. 18, 2024, owned by GAF Energy LLC; and the disclosures of each of the foregoing are incorporated by reference herein in their entireties, with certain different and/or additional features as described herein.

In some embodiments, the roof deck is a sloped roof deck. In some embodiments, the roof deck is a steep slope roof deck.

In some embodiments, the photovoltaic module includes at least one solar cell. In some embodiments, the at least one solar cell includes one solar cell. In some embodiments, the at least one solar cell includes more than one solar cell (e.g., a plurality of solar cells).

In some embodiments, the photovoltaic module includes an encapsulant encapsulating the at least one solar cell. In some embodiments, the encapsulant entirely encapsulates (e.g., fully surrounds) the at least one solar cell.

In some embodiments, the photovoltaic module includes a frontsheet. In some embodiments, the photovoltaic module omits a frontsheet. In some embodiments, the frontsheet contacts a surface of the encapsulant. In some embodiments, the frontsheet contacts a surface of the at least one solar cell.

In some embodiments, the photovoltaic module includes a backsheet. In some embodiments, the photovoltaic module omits a backsheet. In some embodiments, the backsheet contacts a surface of the encapsulant. In some embodiments, the backsheet contacts a surface of the at least one solar cell.

In some embodiments, the at least one solar cell is between the frontsheet and the backsheet. In some embodiments, the encapsulated at least one solar cell is between the frontsheet and the backsheet.

In some embodiments, the backsheet is composed of a polymeric material. In some embodiments, the backsheet is composed of polyethylene terephthalate (“PET”). In some embodiments, the backsheet is composed of ethylene tetrafluoroethylene (“ETFE”). In some embodiments, the backsheet is composed of an acrylic such as polymethyl methacrylate (“PMMA”). In some embodiments, the backsheet is composed of thermoplastic polyolefin (TPO). In some embodiments, the backsheet includes of a single ply TPO roofing membrane. In some embodiments, non-limiting examples of TPO membranes are disclosed in U.S. Pat. No. 9,359,014 to Yang et al., which is incorporated by reference herein in its entirety. In some embodiments, the backsheet is composed of polyvinyl chloride. In some embodiments, the backsheet is composed of ethylene propylene diene monomer (EPDM) rubber. In some embodiments, the backsheet includes a flame retardant additive. In some embodiments, the flame retardant additive may be clays, nanoclays, silicas, carbon black, metal hydroxides such as aluminum hydroxide, metal foils, graphite, and combinations thereof. In some embodiments, the backsheet is composed of foamed TPO. In some embodiments, the backsheet includes at least one layer. In some embodiments, the backsheet includes a plurality of layers. In some embodiments, at least one layer of the backsheet is composed of foamed TPO. In some embodiments, more than one of the layers of the backsheet is composed of foamed TPO.

In some embodiments, the backsheet includes at least one feature to reduce or soften contact stresses between the photovoltaic modules and the roof deck.

In some embodiments, the backsheet includes a plurality of cavities (e.g., cells). In some embodiments, the plurality of cavities reduces or softens contact stresses between the photovoltaic modules and the roof deck. In some embodiments, the backsheet includes a plurality of ribs. In some embodiments, the plurality of ribs reduces or softens contact stresses between the photovoltaic modules and the roof deck.

In some embodiments, the backsheet includes a first layer. In some embodiments, the first layer contacts the roof deck. In some embodiments, the first layer includes the cavities. In some embodiments, the first layer includes the ribs. In some embodiments, the first layer includes the cavities and the ribs.

In some embodiments, the first layer contacts the encapsulant. In some embodiments, the first layer does not contact the encapsulant. In some embodiments, the first layer contacts the at least one solar cell. In some embodiments, the first layer does not contact the at least one solar cell.

In some embodiments, the backsheet includes more than one layer (e.g., the backsheet includes multiple layers). In some embodiments, the backsheet includes a second layer. In some embodiments, the second layer contacts the first layer. In some embodiments, the second layer contacts the encapsulant. In some embodiments, the second layer does not contact the encapsulant. In some embodiments, the second layer contacts the at least one solar cell. In some embodiments, the second layer does not contact the at least one solar cell.

In some embodiments, the backsheet or the first layer of the backsheet has a thickness of 10 mil. In some embodiments, the thickness is 20 mil. In some embodiments, the thickness is 30 mil. In some embodiments, the thickness is 40 mil. In some embodiments, the thickness is 50 mil. In some embodiments, the thickness is 60 mil. In some embodiments, the thickness is 60 mil. In some embodiments, the thickness is 70 mil. In some embodiments, the thickness is 80 mil. In some embodiments, the thickness is 90 mil. In some embodiments, the thickness is 100 mil.

In some embodiments, the thickness is more than 10 mil. In some embodiments, the thickness is more than 20 mil. In some embodiments, the thickness is more than 30 mil. In some embodiments, the thickness is more than 40 mil. In some embodiments, the thickness is more than 50 mil. In some embodiments, the thickness is more than 60 mil. In some embodiments, the thickness is more than 70 mil. In some embodiments, the thickness is more than 80 mil. In some embodiments, the thickness is more than 90 mil. In some embodiments, the thickness is more than 100 mil.

In some embodiments, the thickness is less than 10 mil. In some embodiments, the thickness is less than 20 mil. In some embodiments, the thickness is less than 30 mil. In some embodiments, the thickness is less than 40 mil. In some embodiments, the thickness is less than 50 mil. In some embodiments, the thickness is less than 60 mil. In some embodiments, the thickness is less than 70 mil. In some embodiments, the thickness is less than 80 mil. In some embodiments, the thickness is less than 90 mil. In some embodiments, the thickness is less than 100 mil.

In some embodiments, the thickness is 10 mil to 100 mil. In some embodiments, the thickness is 10 mil to 90 mil. In some embodiments, the thickness is 10 mil to 80 mil. In some embodiments, the thickness is 10 mil to 70 mil. In some embodiments, the thickness is 10 mil to 60 mil. In some embodiments, the thickness is 10 mil to 50 mil. In some embodiments, the thickness is 10 mil to 40 mil. In some embodiments, the thickness is 10 mil to 30 mil. In some embodiments, the thickness is 10 mil to 20 mil.

In some embodiments, the thickness is 20 mil to 100 mil. In some embodiments, the thickness is 20 mil to 90 mil. In some embodiments, the thickness is 20 mil to 80 mil. In some embodiments, the thickness is 20 mil to 70 mil. In some embodiments, the thickness is 20 mil to 60 mil. In some embodiments, the thickness is 20 mil to 50 mil. In some embodiments, the thickness is 20 mil to 40 mil. In some embodiments, the thickness is 20 mil to 30 mil.

In some embodiments, the thickness is 30 mil to 100 mil. In some embodiments, the thickness is 30 mil to 90 mil. In some embodiments, the thickness is 30 mil to 80 mil. In some embodiments, the thickness is 30 mil to 70 mil. In some embodiments, the thickness is 30 mil to 60 mil. In some embodiments, the thickness is 30 mil to 50 mil. In some embodiments, the thickness is 30 mil to 40 mil.

In some embodiments, the thickness is 40 mil to 100 mil. In some embodiments, the thickness is 40 mil to 90 mil. In some embodiments, the thickness is 40 mil to 80 mil. In some embodiments, the thickness is 40 mil to 70 mil. In some embodiments, the thickness is 40 mil to 60 mil. In some embodiments, the thickness is 40 mil to 50 mil.

In some embodiments, the thickness is 50 mil to 100 mil. In some embodiments, the thickness is 50 mil to 90 mil. In some embodiments, the thickness is 50 mil to 80 mil. In some embodiments, the thickness is 50 mil to 70 mil. In some embodiments, the thickness is 50 mil to 60 mil. In some embodiments, the thickness is 60 mil to 100 mil. In some embodiments, the thickness is 60 mil to 90 mil. In some embodiments, the thickness is 60 mil to 80 mil. In some embodiments, the thickness is 60 mil to 70 mil. In some embodiments, the thickness is 70 mil to 100 mil. In some embodiments, the thickness is 70 mil to 90 mil. In some embodiments, the thickness is 70 mil to 80 mil. In some embodiments, the thickness is 80 mil to 100 mil. In some embodiments, the thickness is 80 mil to 90 mil. In some embodiments, the thickness is 90 mil to 100 mil.

In some embodiments, the plurality of cavities includes at least one closed cavity (e.g., a closed cell). In some embodiments, the plurality of cavities includes at least one open cavity (e.g., an open cell). In some embodiments, one or more of the cavities is a closed cavity, and one or more of the cavities is an open cavity.

In some embodiments, at least two of the cavities within the backsheet are in communication with one another. In some embodiments, some of the cavities within the backsheet are not in communication with one another. In some embodiments, none of the cavities within the backsheet are in communication with one another. In some embodiments, the cavities within the backsheet are in communication with the outside of the backsheet (e.g., the outside environment).

In some embodiments, one or more of the cavities have a rectangular cross-section. In some embodiments, one or more of the cavities have a square cross-section. In some embodiments, one or more of the cavities have a triangular cross-section. In some embodiments, one or more of the cavities have a polygonal cross-section. In some embodiments, one or more of the cavities have an elliptical cross-section. In some embodiments, one or more of the cavities have an oval cross-section. In some embodiments, one or more of the cavities have an arcuate cross-section. In some embodiments, two or more of the cavities have the same cross-section. In some embodiments, two or more of the cavities have different cross-sections. In some embodiments, all of the cavities have the same cross-section. In some embodiments, all of the cavities have different cross-sections.

In some embodiments, some or all of the cavities are aligned in a row. In some embodiments, some or all of the cavities are not aligned in a row. In some embodiments, some or all of the cavities are aligned in more than one row. In some embodiments, some or all of the cavities are aligned in two rows. In some embodiments, some or all of the cavities are aligned in three rows. In some embodiments, some or all of the cavities are aligned in four rows. In some embodiments, some or all of the cavities are aligned in more than four rows.

In some embodiments, some or all of the cavities are located equally between an uppermost surface of the backsheet (e.g., a surface closest to the at least one solar cell) and a lowermost surface of the backsheet (e.g., a surface closest to the roof deck when installed thereon). In some embodiments, some or all of the cavities are not located equally between the uppermost surface of the backsheet and the lowermost surface of the backsheet (e.g., a surface closest to the roof deck when installed thereon). In some embodiments, at least some of the cavities are located closer to the uppermost surface of the backsheet than the lowermost surface of the backsheet. In some embodiments, at least some of the cavities are located closer to the lowermost surface of the backsheet than the uppermost surface of the backsheet. In some embodiments, all of the cavities are located closer to the uppermost surface of the backsheet than the lowermost surface of the backsheet. In some embodiments, all of the cavities are located closer to the lowermost surface of the backsheet than the uppermost surface of the backsheet. In some embodiments, all of the cavities are located equally between the uppermost surface of the backsheet and the lowermost surface of the backsheet. In some embodiments, all of the cavities are not located equally between the uppermost surface of the backsheet and the lowermost surface of the backsheet (e.g., a surface closest to the roof deck when installed thereon). In some embodiments, the cavities are located randomly between the uppermost surface of the backsheet to the lowermost surface of the backsheet.

In some embodiments, a dimension of one or more of the cavities is 1 mil. In some embodiments, the dimension is 2 mil. In some embodiments, the dimension is 3 mil. In some embodiments, the dimension is 4 mil. In some embodiments, the dimension is 5 mil. In some embodiments, the dimension is 6 mil. In some embodiments, the dimension is 7 mil. In some embodiments, the dimension is 8 mil. In some embodiments, the dimension is 9 mil. In some embodiments, the dimension is 10 mil. In some embodiments, the dimension is 15 mil. In some embodiments, the dimension is 20 mil. In some embodiments, the dimension is 25 mil. In some embodiments, the dimension is 30 mil. In some embodiments, the dimension is 40 mil. In some embodiments, the dimension is 50 mil. In some embodiments, the dimension is 60 mil. In some embodiments, the dimension is 70 mil. In some embodiments, the dimension is 80 mil. In some embodiments, the dimension is 90 mil. In some embodiments, the dimension is 100 mil. In some embodiments, the dimension is a radius. In some embodiments, the dimension is a length. In some embodiments, the dimension is a width. In some embodiments, the dimension is a height.

In some embodiments, the dimension is more than 1 mil. In some embodiments, the dimension is more than 2 mil. In some embodiments, the dimension is more than 3 mil. In some embodiments, the dimension is more than 4 mil. In some embodiments, the dimension is more than 5 mil. In some embodiments, the dimension is more than 6 mil. In some embodiments, the dimension is more than 7 mil. In some embodiments, the dimension is more than 8 mil. In some embodiments, the dimension is more than 9 mil. In some embodiments, the dimension is more than 10 mil. In some embodiments, the dimension is more than 15 mil. In some embodiments, the dimension is more than 20 mil. In some embodiments, the dimension is more than 25 mil. In some embodiments, the dimension is more than 30 mil. In some embodiments, the dimension is more than 40 mil. In some embodiments, the dimension is more than 50 mil. In some embodiments, the dimension is more than 60 mil. In some embodiments, the dimension is more than 70 mil. In some embodiments, the dimension is more than 80 mil. In some embodiments, the dimension is more than 90 mil. In some embodiments, the dimension is more than 100 mil.

In some embodiments, the dimension is less than 1 mil. In some embodiments, the dimension is less than 2 mil. In some embodiments, the dimension is less than 3 mil. In some embodiments, the dimension is less than 4 mil. In some embodiments, the dimension is less than 5 mil. In some embodiments, the dimension is less than 6 mil. In some embodiments, the dimension is less than 7 mil. In some embodiments, the dimension is less than 8 mil. In some embodiments, the dimension is less than 9 mil. In some embodiments, the dimension is less than 10 mil. In some embodiments, the dimension is less than 15 mil. In some embodiments, the dimension is less than 20 mil. In some embodiments, the dimension is less than 25 mil. In some embodiments, the dimension is less than 30 mil. In some embodiments, the dimension is less than 40 mil. In some embodiments, the dimension is less than 50 mil. In some embodiments, the dimension is less than 60 mil. In some embodiments, the dimension is less than 70 mil. In some embodiments, the dimension is less than 80 mil. In some embodiments, the dimension is less than 90 mil. In some embodiments, the dimension is less than 100 mil.

In some embodiments, the dimension is 1 mil to 100 mil. In some embodiments, the dimension is 1 mil to 80 mil. In some embodiments, the dimension is 1 mil to 90 mil. In some embodiments, the dimension is 1 mil to 70 mil. In some embodiments, the dimension is 1 mil to 60 mil. In some embodiments, the dimension is 1 mil to 50 mil. In some embodiments, the dimension is 1 mil to 40 mil. In some embodiments, the dimension is 1 mil to 30 mil. some embodiments, the dimension is 1 mil to 25 mil. In some embodiments, the dimension is 1 mil to 20 mil. In some embodiments, the dimension is 1 mil to 15 mil. In some embodiments, the dimension is 1 mil to 10 mil. In some embodiments, the dimension is 1 mil to 9 mil. In some embodiments, the dimension is 1 mil to 8 mil. In some embodiments, the dimension is 1 mil to 7 mil. In some embodiments, the dimension is 1 mil to 6 mil. In some embodiments, the dimension is 1 mil to 5 mil. In some embodiments, the dimension is 1 mil to 4 mil. In some embodiments, the dimension is 1 mil to 3 mil. In some embodiments, the dimension is 1 mil to 2 mil.

In some embodiments, the dimension is 2 mil to 100 mil. In some embodiments, the dimension is 2 mil to 90 mil. In some embodiments, the dimension is 2 mil to 80 mil. In some embodiments, the dimension is 2 mil to 70 mil. In some embodiments, the dimension is 2 mil to 60 mil. In some embodiments, the dimension is 2 mil to 50 mil. In some embodiments, the dimension is 2 mil to 40 mil. In some embodiments, the dimension is 2 mil to 30 mil. In some embodiments, the dimension is 2 mil to 25 mil. In some embodiments, the dimension is 2 mil to 20 mil. In some embodiments, the dimension is 2 mil to 15 mil. In some embodiments, the dimension is 2 mil to 10 mil. In some embodiments, the dimension is 2 mil to 9 mil. In some embodiments, the dimension is 2 mil to 8 mil. In some embodiments, the dimension is 2 mil to 7 mil. In some embodiments, the dimension is 2 mil to 6 mil. In some embodiments, the dimension is 2 mil to 5 mil. In some embodiments, the dimension is 2 mil to 4 mil. In some embodiments, the dimension is 2 mil to 3 mil.

In some embodiments, the dimension is 3 mil to 100 mil. In some embodiments, the dimension is 3 mil to 90 mil. In some embodiments, the dimension is 3 mil to 80 mil. In some embodiments, the dimension is 3 mil to 70 mil. In some embodiments, the dimension is 3 mil to 70 mil. In some embodiments, the dimension is 3 mil to 60 mil. In some embodiments, the dimension is 3 mil to 50 mil. In some embodiments, the dimension is 3 mil to 40 mil. In some embodiments, the dimension is 3 mil to 30 mil. In some embodiments, the dimension is 3 mil to 25 mil. In some embodiments, the dimension is 3 mil to 20 mil. In some embodiments, the dimension is 3 mil to 15 mil. In some embodiments, the dimension is 3 mil to 10 mil. In some embodiments, the dimension is 3 mil to 9 mil. In some embodiments, the dimension is 3 mil to 8 mil. In some embodiments, the dimension is 3 mil to 7 mil. In some embodiments, the dimension is 3 mil to 6 mil. In some embodiments, the dimension is 3 mil to 5 mil. In some embodiments, the dimension is 3 mil to 4 mil.

In some embodiments, the dimension is 4 mil to 100 mil. In some embodiments, the dimension is 4 mil to 90 mil. In some embodiments, the dimension is 4 mil to 80 mil. In some embodiments, the dimension is 4 mil to 70 mil. In some embodiments, the dimension is 4 mil to 60 mil. In some embodiments, the dimension is 4 mil to 50 mil. In some embodiments, the dimension is 4 mil to 40 mil. In some embodiments, the dimension is 4 mil to 30 mil. In some embodiments, the dimension is 4 mil to 25 mil. In some embodiments, the dimension is 4 mil to 20 mil. In some embodiments, the dimension is 4 mil to 15 mil. In some embodiments, the dimension is 4 mil to 10 mil. In some embodiments, the dimension is 4 mil to 9 mil. In some embodiments, the dimension is 4 mil to 8 mil. In some embodiments, the dimension is 4 mil to 7 mil. In some embodiments, the dimension is 4 mil to 6 mil. In some embodiments, the dimension is 4 mil to 5 mil.

In some embodiments, the dimension is 5 mil to 100 mil. In some embodiments, the dimension is 5 mil to 90 mil. In some embodiments, the dimension is 5 mil to 80 mil. In some embodiments, the dimension is 5 mil to 70 mil. In some embodiments, the dimension is 5 mil to 60 mil. In some embodiments, the dimension is 5 mil to 50 mil. In some embodiments, the dimension is 5 mil to 40 mil. In some embodiments, the dimension is 5 mil to 30 mil. In some embodiments, the dimension is 5 mil to 25 mil. In some embodiments, the dimension is 5 mil to 20 mil. In some embodiments, the dimension is 5 mil to 15 mil. In some embodiments, the dimension is 5 mil to 10 mil. In some embodiments, the dimension is 5 mil to 9 mil. In some embodiments, the dimension is 5 mil to 8 mil. In some embodiments, the dimension is 5 mil to 7 mil. In some embodiments, the dimension is 5 mil to 6 mil.

In some embodiments, the dimension is 6 mil to 100 mil. In some embodiments, the dimension is 6 mil to 90 mil. In some embodiments, the dimension is 6 mil to 80 mil. In some embodiments, the dimension is 6 mil to 70 mil. In some embodiments, the dimension is 6 mil to 60 mil. In some embodiments, the dimension is 6 mil to 50 mil. In some embodiments, the dimension is 6 mil to 40 mil. In some embodiments, the dimension is 6 mil to 30 mil. In some embodiments, the dimension is 6 mil to 25 mil. In some embodiments, the dimension is 6 mil to 20 mil. In some embodiments, the dimension is 6 mil to 15 mil. In some embodiments, the dimension is 6 mil to 10 mil. In some embodiments, the dimension is 6 mil to 9 mil. In some embodiments, the dimension is 6 mil to 8 mil. In some embodiments, the dimension is 6 mil to 7 mil.

In some embodiments, the dimension is 7 mil to 100 mil. In some embodiments, the dimension is 7 mil to 90 mil. In some embodiments, the dimension is 7 mil to 80 mil. In some embodiments, the dimension is 7 mil to 70 mil. In some embodiments, the dimension is 7 mil to 60 mil. In some embodiments, the dimension is 7 mil to 50 mil. In some embodiments, the dimension is 7 mil to 40 mil. In some embodiments, the dimension is 7 mil to 30 mil. In some embodiments, the dimension is 7 mil to 25 mil. In some embodiments, the dimension is 7 mil to 20 mil. In some embodiments, the dimension is 7 mil to 15 mil. In some embodiments, the dimension is 7 mil to 10 mil. In some embodiments, the dimension is 7 mil to 9 mil. In some embodiments, the dimension is 7 mil to 8 mil.

In some embodiments, the dimension is 8 mil to 100 mil. In some embodiments, the dimension is 8 mil to 90 mil. In some embodiments, the dimension is 8 mil to 80 mil. In some embodiments, the dimension is 8 mil to 70 mil. In some embodiments, the dimension is 8 mil to 60 mil. In some embodiments, the dimension is 8 mil to 50 mil. In some embodiments, the dimension is 8 mil to 40 mil. In some embodiments, the dimension is 8 mil to 30 mil. In some embodiments, the dimension is 8 mil to 25 mil. In some embodiments, the dimension is 8 mil to 20 mil. In some embodiments, the dimension is 8 mil to 15 mil. In some embodiments, the dimension is 8 mil to 10 mil. In some embodiments, the dimension is 8 mil to 9 mil.

In some embodiments, the dimension is 9 mil to 100 mil. In some embodiments, the dimension is 9 mil to 90 mil. In some embodiments, the dimension is 9 mil to 80 mil. In some embodiments, the dimension is 9 mil to 70 mil. In some embodiments, the dimension is 9 mil to 60 mil. In some embodiments, the dimension is 9 mil to 50 mil. In some embodiments, the dimension is 9 mil to 40 mil. In some embodiments, the dimension is 9 mil to 30 mil. In some embodiments, the dimension is 9 mil to 25 mil. In some embodiments, the dimension is 9 mil to 20 mil. In some embodiments, the dimension is 9 mil to 15 mil. In some embodiments, the dimension is 9 mil to 10 mil.

In some embodiments, the dimension is 10 mil to 100 mil. In some embodiments, the dimension is 10 mil to 90 mil. In some embodiments, the dimension is 10 mil to 80 mil. In some embodiments, the dimension is 10 mil to 70 mil. In some embodiments, the dimension is 10 mil to 60 mil. In some embodiments, the dimension is 10 mil to 50 mil. In some embodiments, the dimension is 10 mil to 40 mil. In some embodiments, the dimension is 10 mil to 30 mil. In some embodiments, the dimension is 10 mil to 25 mil. In some embodiments, the dimension is 10 mil to 20 mil. In some embodiments, the dimension is 10 mil to 15 mil.

In some embodiments, the dimension is 15 mil to 100 mil. In some embodiments, the dimension is 15 mil to 90 mil. In some embodiments, the dimension is 15 mil to 80 mil. In some embodiments, the dimension is 15 mil to 70 mil. In some embodiments, the dimension is 15 mil to 60 mil. In some embodiments, the dimension is 15 mil to 50 mil. In some embodiments, the dimension is 15 mil to 40 mil. In some embodiments, the dimension is 15 mil to 30 mil. In some embodiments, the dimension is 15 mil to 25 mil. In some embodiments, the dimension is 15 mil to 20 mil. In some embodiments, the dimension is 20 mil to 70 mil. In some embodiments, the dimension is 20 mil to 60 mil. In some embodiments, the dimension is 20 mil to 50 mil. In some embodiments, the dimension is 20 mil to 40 mil. In some embodiments, the dimension is 20 mil to 30 mil. In some embodiments, the dimension is 20 mil to 25 mil.

In some embodiments, the dimension is 25 mil to 100 mil. In some embodiments, the dimension is 25 mil to 90 mil. In some embodiments, the dimension is 25 mil to 80 mil. In some embodiments, the dimension is 25 mil to 70 mil. In some embodiments, the dimension is 25 mil to 60 mil. In some embodiments, the dimension is 25 mil to 50 mil. In some embodiments, the dimension is 25 mil to 40 mil. In some embodiments, the dimension is 25 mil to 30 mil.

In some embodiments, the dimension is 30 mil to 100 mil. In some embodiments, the dimension is 30 mil to 90 mil. In some embodiments, the dimension is 30 mil to 80 mil. In some embodiments, the dimension is 30 mil to 70 mil. In some embodiments, the dimension is 30 mil to 60 mil. In some embodiments, the dimension is 30 mil to 50 mil. In some embodiments, the dimension is 30 mil to 40 mil. In some embodiments, the dimension is 40 mil to 100 mil. In some embodiments, the dimension is 40 mil to 90 mil. In some embodiments, the dimension is 40 mil to 80 mil. In some embodiments, the dimension is 40 mil to 70 mil. In some embodiments, the dimension is 40 mil to 60 mil. In some embodiments, the dimension is 40 mil to 50 mil.

In some embodiments, the dimension is 50 mil to 100 mil. In some embodiments, the dimension is 50 mil to 90 mil. In some embodiments, the dimension is 50 mil to 80 mil. In some embodiments, the dimension is 50 mil to 70 mil. In some embodiments, the dimension is 50 mil to 60 mil. In some embodiments, the dimension is 60 mil to 100 mil. In some embodiments, the dimension is 60 mil to 90 mil. In some embodiments, the dimension is 60 mil to 80 mil. In some embodiments, the dimension is 60 mil to 70 mil. In some embodiments, the dimension is 70 mil to 100 mil. In some embodiments, the dimension is 70 mil to 90 mil. In some embodiments, the dimension is 70 mil to 80 mil. In some embodiments, the dimension is 80 mil to 100 mil. In some embodiments, the dimension is 80 mil to 90 mil. In some embodiments, the dimension is 90 mil to 100 mil.

In some embodiments, the photovoltaic module includes a filler material in at least one cavity. In some embodiments, the photovoltaic module includes the filler material in all of the cavities. In some embodiments, the filler material in at least one of the cavities includes a fire-retardant material. In some embodiments, the filler material in all of the cavities includes a fire-retardant material. In some embodiments, the filler material modifies the fire-resistance of the backsheet. In some embodiments, the filler material modifies the fire-resistance of the photovoltaic module.

In some embodiments, the fire-retardant material includes one or more of colemanite, aluminum trihydrate, magnesium hydroxide, expandable graphite, ammonium polyphosphate, triphenyl phosphate, resorcinol bis(diphenylphosphate), bisphenol A diphenyl phosphate, tricresyl phosphate, dimethyl methylphosphonate, aluminum diethyl phosphinate, decabromodiphenyl ether, decabromodiphenyl ethane, at least one brominated polystyrene, at least one brominated carbonate oligomer, at least one brominated epoxy oligomer, tetrabromophthalic anhydride, tetrabromobisphenol A, hexabromocyclododecane, antimony trioxide, antimony pentoxide, at least one chlorinated paraffin, huntite, hydromagnesite, red phosphorous, zinc borate, sodium borate, lithium borate, boric acid, tris(1,3-dichloro-2-propyl)phosphate, tetrakis(2-chloroethyl)dichloroisopentyldiphosphate, or any combination thereof.

In some embodiments, the filler material in at least one of the cavities includes a phase-change material. In some embodiments, the filler material in all of the cavities includes the phase-change material. In some embodiments, the phase-change material modifies the thermal resistance of the backsheet. In some embodiments, the phase-change material modifies the thermal resistance of the photovoltaic module.

In some embodiments, the phase-change material includes a hydrated salt. In some embodiments, the hydrated salt comprises calcium. In some embodiments, the hydrated salt comprises sodium. In some embodiments, the material includes at least one of sodium disulfite pentahydrate, NaCH₃COO·3H₂O, Mg(NO₃)₂·6H₂O/Mg(NO₃)₂·2H₂O, propionamide/palmitic acid, camphene, myristic acid, sodium sulfite decahydrate, Na₂HPO₄·12H₂O, Zn(NO₃)₂·6H₂O, Na₂SO₄·10H₂O/NH₄Cl/KCl, PE Glycol, CaCl₂/CaBr₂/6H₂O/KBr, CaCl₂/CaBr₂/6H₂O, Na₂SO₄·10H₂O/NaCl, PE Glycol, CaCl₂·6H₂O, Na₂SO₄·10H₂O, CaBr₂·6H₂O, Neopentyl glycol, Na₂S₂O₃·5H₂O, Paraffin wax, MgCl₂/Mg(NO₃)₂·6H₂O, NaCO₂CH₃·3H₂O, Na₄P₂O₇·10H₂O, Mg(NO₃)₂·6H₂O, MgCl₂·6H₂O, polyethylene, tetradecane, pentadecane, hexadecane (cetane), heptadecane, octadecane, nonadecane, eicosane, heneicosane, docosane, tricosane, tetracosane, pentacosane, hexacosane, heptacosane, octacosane, nonacosane, triacontane, or any combination thereof.

In some embodiments, the filler material includes a gas. In some embodiments, the gas includes air. In some embodiments, the gas includes an inert gas. In some embodiments, the inert gas includes helium, neon, argon, krypton, xenon, radon. In some embodiments, the gas includes nitrogen. In some embodiments, the gas includes carbon dioxide. In some embodiments, the gas includes combinations of one or more of any of the listed gases, with and/or without one or more other gas and/or gases.

In some embodiments, different cavities include different filler materials—for example, in some embodiments, at least one of the cavities includes a fire-retardant material, and at least one of the cavities include a phase-change material. In some embodiments, one or more cavities includes a fire-retardant and a phase-change material. In some embodiments, the fire-retardant material comprises a liquid.

In some embodiments, the cavities include one or more channels. In some embodiments, one or more channels extend between opposite ends of the first layer. In some embodiments, the one or more channels are located within a lower-most surface of the backsheet. In some embodiments, the backsheet includes one channel. In some embodiments, the backsheet includes a plurality of channels. In some embodiments, the plurality of channels includes two channels. In some embodiments, the plurality of channels includes three channels. In some embodiments, the plurality of channels includes four channels. In some embodiments, the plurality of channels includes five channels. In some embodiments, the plurality of channels includes six channels. In some embodiments, the plurality of channels includes seven channels. In some embodiments, the plurality of channels includes eight channels. In some embodiments, the plurality of channels includes more than eight channels.

In some embodiments, one or more of the channels extend along a major dimension of the photovoltaic module, between opposite ends of the backsheet (e.g., from one end of the photovoltaic module to another end of the photovoltaic module, along the longest dimension of the photovoltaic module). In some embodiments, all of the channels extend along the major dimension of the photovoltaic module between opposite ends of the backsheet (e.g., from one end of the photovoltaic module to another end of the photovoltaic module). In some embodiments, one or more of the channels is open on both ends. In some embodiments, one or more of the channels is sealed on at least one end. In some embodiments, one or more of the channels is sealed at both ends.

In some embodiments, one or more of the channels do not extend from one end of the photovoltaic module to another end of the photovoltaic module, but instead are located within an interior of the backsheet. In some embodiments, none of the channels extend from one end of the photovoltaic module to another end of the photovoltaic module, but instead all of the channels are located within the interior of the backsheet.

In some embodiments, the first layer includes a plurality of ribs extending along the major dimension of the photovoltaic module, between opposite ends of the first layer. In some embodiments, when the photovoltaic module is installed on the roof deck, the plurality of ribs are on a lowermost surface of the photovoltaic module, and contact the roof deck. In some embodiments, when the photovoltaic module is installed on the roof deck, the plurality of ribs form a lowermost surface of the photovoltaic module, and contact the roof deck

In some embodiments, the plurality of ribs includes at least two ribs. In some embodiments, the plurality of ribs includes two ribs. In some embodiments, the plurality of ribs includes three ribs. In some embodiments, the plurality of ribs includes four ribs. In some embodiments, the plurality of ribs includes five ribs. In some embodiments, the plurality of ribs includes six ribs. In some embodiments, the plurality of ribs includes seven ribs. In some embodiments, the plurality of ribs includes eight ribs. In some embodiments, the plurality of ribs includes more than eight ribs.

In some embodiments, a depth of the rib is 5% of the total thickness of the backsheet or of a lowermost layer of the backsheet (e.g., a layer of the backsheet closest to the roof deck, in which the rib is formed). In some embodiments, the depth of the rib is 10% of the total thickness. In some embodiments, the depth of the rib is 15% of the total thickness. In some embodiments, the depth of the rib is 20% of the total thickness. In some embodiments, the depth of the rib is 25% of the total thickness. In some embodiments, the depth of the rib is 30% of the total thickness. In some embodiments, the depth of the rib is 35% of the total thickness. In some embodiments, the depth of the rib is 40% of the total thickness. In some embodiments, the depth of the rib is 45% of the total thickness In some embodiments, the depth of the rib is 50% of the total thickness. In some embodiments, the depth of the rib is 60% of the total thickness. In some embodiments, the depth of the rib is 70% of the total thickness. In some embodiments, the depth of the rib is 80% of the total thickness. In some embodiments, the depth of the rib is 90% of the total thickness. In some embodiments, the depth of the rib is 95% of the total thickness. In some embodiments, the depth of the rib is 99% of the total thickness.

In some embodiments, the depth of the rib is more than 5% of the total thickness. In some embodiments, the depth of the rib is more than 10% of the total thickness. In some embodiments, the depth of the rib is more than 15% of the total thickness. In some embodiments, the depth of the rib is more than 20% of the total thickness. In some embodiments, the depth of the rib is more than 25% of the total thickness. In some embodiments, the depth of the rib is more than 30% of the total thickness. In some embodiments, the depth of the rib is more than 35% of the total thickness. In some embodiments, the depth of the rib is more than 40% of the total thickness. In some embodiments, the depth of the rib is more than 45% of the total thickness. In some embodiments, the depth of the rib is more than 50% of the total thickness. In some embodiments, the depth of the rib is more than 60% of the total thickness. In some embodiments, the depth of the rib is more than 70% of the total thickness. In some embodiments, the depth of the rib is more than 80% of the total thickness. In some embodiments, the depth of the rib is more than 90% of the total thickness. In some embodiments, the depth of the rib is more than 95% of the total thickness. In some embodiments, the depth of the rib is more than 99% of the total thickness.

In some embodiments, the depth of the rib is less than 5% of the total thickness. In some embodiments, the depth of the rib is less than 10% of the total thickness. In some embodiments, the depth of the rib is less than 15% of the total thickness. In some embodiments, the depth of the rib is less than 20% of the total thickness. In some embodiments, the depth of the rib is less than 25% of the total thickness. In some embodiments, the depth of the rib is less than 30% of the total thickness. In some embodiments, the depth of the rib is less than 35% of the total thickness. In some embodiments, the depth of the rib is less than 40% of the total thickness. In some embodiments, the depth of the rib is less than 45% of the total thickness. In some embodiments, the depth of the rib is less than 50% of the total thickness. In some embodiments, the depth of the rib is less than 60% of the total thickness. In some embodiments, the depth of the rib is less than 70% of the total thickness. In some embodiments, the depth of the rib is less than 80% of the total thickness. In some embodiments, the depth of the rib is less than 90% of the total thickness. In some embodiments, the depth of the rib is less than 95% of the total thickness. In some embodiments, the depth of the rib is less than 99% of the total thickness.

In some embodiments, the depth of the rib is 5% to 99% of the total thickness. In some embodiments, the depth of the rib is 10% to 99% of the total thickness. In some embodiments, the depth of the rib is 15% to 99% of the total thickness. In some embodiments, the depth of the rib is 20% to 99% of the total thickness. In some embodiments, the depth of the rib is 25% to 99% of the total thickness. In some embodiments, the depth of the rib is 30% to 99% of the total thickness. In some embodiments, the depth of the rib is 35% to 99% of the total thickness. In some embodiments, the depth of the rib is 40% to 99% of the total thickness. In some embodiments, the depth of the rib is 45% to 99% of the total thickness. In some embodiments, the depth of the rib is 50% to 99% of the total thickness. In some embodiments, the depth of the rib is 60% to 99% of the total thickness. In some embodiments, the depth of the rib is 70% to 99% of the total thickness. In some embodiments, the depth of the rib is 80% to 99% of the total thickness. In some embodiments, the depth of the rib is 90% to 99% of the total thickness. In some embodiments, the depth of the rib is 95% to 99% of the total thickness.

In some embodiments, the depth of the rib is 5% to 95% of the total thickness. In some embodiments, the depth of the rib is 10% to 95% of the total thickness. In some embodiments, the depth of the rib is 15% to 95% of the total thickness. In some embodiments, the depth of the rib is 20% to 95% of the total thickness. In some embodiments, the depth of the rib is 25% to 95% of the total thickness. In some embodiments, the depth of the rib is 30% to 95% of the total thickness. In some embodiments, the depth of the rib is 35% to 95% of the total thickness. In some embodiments, the depth of the rib is 40% to 95% of the total thickness. In some embodiments, the depth of the rib is 45% to 95% of the total thickness. In some embodiments, the depth of the rib is 50% to 95% of the total thickness. In some embodiments, the depth of the rib is 60% to 95% of the total thickness. In some embodiments, the depth of the rib is 70% to 95% of the total thickness. In some embodiments, the depth of the rib is 80% to 95% of the total thickness. In some embodiments, the depth of the rib is 90% to 95% of the total thickness.

In some embodiments, the depth of the rib is 5% to 90% of the total thickness. In some embodiments, the depth of the rib is 10% to 90% of the total thickness. In some embodiments, the depth of the rib is 15% to 90% of the total thickness. In some embodiments, the depth of the rib is 20% to 90% of the total thickness. In some embodiments, the depth of the rib is 25% to 90% of the total thickness. In some embodiments, the depth of the rib is 30% to 90% of the total thickness. In some embodiments, the depth of the rib is 35% to 90% of the total thickness. In some embodiments, the depth of the rib is 40% to 90% of the total thickness. In some embodiments, the depth of the rib is 45% to 90% of the total thickness. In some embodiments, the depth of the rib is 50% to 90% of the total thickness. In some embodiments, the depth of the rib is 60% to 90% of the total thickness. In some embodiments, the depth of the rib is 70% to 90% of the total thickness. In some embodiments, the depth of the rib is 80% to 90% of the total thickness.

In some embodiments, the depth of the rib is 5% to 80% of the total thickness. In some embodiments, the depth of the rib is 10% to 80% of the total thickness. In some embodiments, the depth of the rib is 15% to 80% of the total thickness. In some embodiments, the depth of the rib is 20% to 80% of the total thickness. In some embodiments, the depth of the rib is 25% to 80% of the total thickness. In some embodiments, the depth of the rib is 30% to 80% of the total thickness. In some embodiments, the depth of the rib is 35% to 80% of the total thickness. In some embodiments, the depth of the rib is 40% to 80% of the total thickness. In some embodiments, the depth of the rib is 45% to 80% of the total thickness. In some embodiments, the depth of the rib is 50% to 80% of the total thickness. In some embodiments, the depth of the rib is 60% to 80% of the total thickness. In some embodiments, the depth of the rib is 70% to 80% of the total thickness.

In some embodiments, the depth of the rib is 5% to 70% of the total thickness. In some embodiments, the depth of the rib is 10% to 70% of the total thickness. In some embodiments, the depth of the rib is 15% to 70% of the total thickness. In some embodiments, the depth of the rib is 20% to 70% of the total thickness. In some embodiments, the depth of the rib is 25% to 70% of the total thickness. In some embodiments, the depth of the rib is 30% to 70% of the total thickness. In some embodiments, the depth of the rib is 35% to 70% of the total thickness. In some embodiments, the depth of the rib is 40% to 70% of the total thickness. In some embodiments, the depth of the rib is 45% to 70% of the total thickness. In some embodiments, the depth of the rib is 50% to 70% of the total thickness. In some embodiments, the depth of the rib is 60% to 70% of the total thickness.

In some embodiments, the depth of the rib is 5% to 60% of the total thickness. In some embodiments, the depth of the rib is 10% to 60% of the total thickness. In some embodiments, the depth of the rib is 15% to 60% of the total thickness. In some embodiments, the depth of the rib is 20% to 60% of the total thickness. In some embodiments, the depth of the rib is 25% to 60% of the total thickness. In some embodiments, the depth of the rib is 30% to 60% of the total thickness. In some embodiments, the depth of the rib is 35% to 60% of the total thickness. In some embodiments, the depth of the rib is 40% to 60% of the total thickness. In some embodiments, the depth of the rib is 45% to 60% of the total thickness. In some embodiments, the depth of the rib is 50% to 60% of the total thickness.

In some embodiments, the depth of the rib is 5% to 50% of the total thickness. In some embodiments, the depth of the rib is 10% to 50% of the total thickness. In some embodiments, the depth of the rib is 15% to 50% of the total thickness. In some embodiments, the depth of the rib is 20% to 50% of the total thickness. In some embodiments, the depth of the rib is 25% to 50% of the total thickness. In some embodiments, the depth of the rib is 30% to 50% of the total thickness. In some embodiments, the depth of the rib is 35% to 50% of the total thickness. In some embodiments, the depth of the rib is 40% to 50% of the total thickness. In some embodiments, the depth of the rib is 45% to 50% of the total thickness.

In some embodiments, the depth of the rib is 5% to 45% of the total thickness. In some embodiments, the depth of the rib is 10% to 45% of the total thickness. In some embodiments, the depth of the rib is 15% to 45% of the total thickness. In some embodiments, the depth of the rib is 20% to 45% of the total thickness. In some embodiments, the depth of the rib is 25% to 45% of the total thickness. In some embodiments, the depth of the rib is 30% to 45% of the total thickness. In some embodiments, the depth of the rib is 35% to 45% of the total thickness. In some embodiments, the depth of the rib is 40% to 45% of the total thickness.

In some embodiments, the depth of the rib is 5% to 40% of the total thickness. In some embodiments, the depth of the rib is 10% to 40% of the total thickness. In some embodiments, the depth of the rib is 15% to 40% of the total thickness. In some embodiments, the depth of the rib is 20% to 40% of the total thickness. In some embodiments, the depth of the rib is 25% to 40% of the total thickness. In some embodiments, the depth of the rib is 30% to 40% of the total thickness. In some embodiments, the depth of the rib is 35% to 40% of the total thickness.

In some embodiments, the depth of the rib is 5% to 35% of the total thickness. In some embodiments, the depth of the rib is 10% to 35% of the total thickness. In some embodiments, the depth of the rib is 15% to 35% of the total thickness. In some embodiments, the depth of the rib is 20% to 35% of the total thickness. In some embodiments, the depth of the rib is 25% to 35% of the total thickness. In some embodiments, the depth of the rib is 30% to 35% of the total thickness.

In some embodiments, the depth of the rib is 5% to 30% of the total thickness. In some embodiments, the depth of the rib is 10% to 30% of the total thickness. In some embodiments, the depth of the rib is 15% to 30% of the total thickness. In some embodiments, the depth of the rib is 20% to 30% of the total thickness. In some embodiments, the depth of the rib is 25% to 30% of the total thickness. In some embodiments, the depth of the rib is 5% to 25% of the total thickness. In some embodiments, the depth of the rib is 10% to 25% of the total thickness. In some embodiments, the depth of the rib is 15% to 25% of the total thickness. In some embodiments, the depth of the rib is 20% to 25% of the total thickness.

In some embodiments, the depth of the rib is 5% to 20% of the total thickness. In some embodiments, the depth of the rib is 10% to 20% of the total thickness. In some embodiments, the depth of the rib is 15% to 20% of the total thickness. In some embodiments, the depth of the rib is 5% to 15% of the total thickness. In some embodiments, the depth of the rib is 10% to 15% of the total thickness. In some embodiments, the depth of the rib is 5% to 10% of the total thickness.

In some embodiments, the depth of the rib is 1 mil. In some embodiments, the depth of the rib is 2 mil. In some embodiments, the depth of the rib is 3 mil. In some embodiments, the depth of the rib is 4 mil. In some embodiments, the depth of the rib is 5 mil. In some embodiments, the depth of the rib is 6 mil. In some embodiments, the depth of the rib is 7 mil. In some embodiments, the depth of the rib is 8 mil. In some embodiments, the depth of the rib is 9 mil. In some embodiments, the depth of the rib is 10 mil. In some embodiments, the depth of the rib is 15 mil. In some embodiments, the depth of the rib is 20 mil. In some embodiments, the depth of the rib is 30 mil. In some embodiments, the depth of the rib is 40 mil. In some embodiments, the depth of the rib is 50 mil.

In some embodiments, the depth of the rib is more than 1 mil. In some embodiments, the depth of the rib is more than 2 mil. In some embodiments, the depth of the rib is more than 3 mil. In some embodiments, the depth of the rib is more than 4 mil. In some embodiments, the depth of the rib is more than 5 mil. In some embodiments, the depth of the rib is more than 6 mil. In some embodiments, the depth of the rib is more than 7 mil. In some embodiments, the depth of the rib is more than 8 mil. In some embodiments, the depth of the rib is more than 9 mil. In some embodiments, the depth of the rib is more than 10 mil. In some embodiments, the depth of the rib is more than 15 mil. In some embodiments, the depth of the rib is more than 20 mil. In some embodiments, the depth of the rib is more than 30 mil. In some embodiments, the depth of the rib is more than 40 mil. In some embodiments, the depth of the rib is more than 50 mil.

In some embodiments, the depth of the rib is less than 1 mil. In some embodiments, the depth of the rib is less than 2 mil. In some embodiments, the depth of the rib is less than 3 mil. In some embodiments, the depth of the rib is less than 4 mil. In some embodiments, the depth of the rib is less than 5 mil. In some embodiments, the depth of the rib is less than 6 mil. In some embodiments, the depth of the rib is less than 7 mil. In some embodiments, the depth of the rib is less than 8 mil. In some embodiments, the depth of the rib is less than 9 mil. In some embodiments, the depth of the rib is less than 10 mil. In some embodiments, the depth of the rib is less than 15 mil. In some embodiments, the depth of the rib is less than 20 mil. In some embodiments, the depth of the rib is less than 30 mil. In some embodiments, the depth of the rib is less than 40 mil. In some embodiments, the depth of the rib is less than 50 mil.

In some embodiments, the depth of the rib is 1 mil to 50 mil. In some embodiments, the depth of the rib is 2 mil to 50 mil. In some embodiments, the depth of the rib is 3 mil to 50 mil. In some embodiments, the depth of the rib is 4 mil to 50 mil. In some embodiments, the depth of the rib is 5 mil to 50 mil. In some embodiments, the depth of the rib is 6 mil to 50 mil. In some embodiments, the depth of the rib is 7 mil to 50 mil. In some embodiments, the depth of the rib is 8 mil to 50 mil. In some embodiments, the depth of the rib is 9 mil to 50 mil. In some embodiments, the depth of the rib is 10 mil to 50 mil. In some embodiments, the depth of the rib is 15 mil to 50 mil. In some embodiments, the depth of the rib is 20 mil to 50 mil. In some embodiments, the depth of the rib is 30 mil to 50 mil. In some embodiments, the depth of the rib is 40 mil to 50 mil.

In some embodiments, the depth of the rib is 1 mil to 40 mil. In some embodiments, the depth of the rib is 2 mil to 40 mil. In some embodiments, the depth of the rib is 3 mil to 40 mil. In some embodiments, the depth of the rib is 4 mil to 40 mil. In some embodiments, the depth of the rib is 5 mil to 40 mil. In some embodiments, the depth of the rib is 6 mil to 40 mil. In some embodiments, the depth of the rib is 7 mil to 40 mil. In some embodiments, the depth of the rib is 8 mil to 40 mil. In some embodiments, the depth of the rib is 9 mil to 40 mil. In some embodiments, the depth of the rib is 10 mil to 40 mil. In some embodiments, the depth of the rib is 15 mil to 40 mil. In some embodiments, the depth of the rib is 20 mil to 40 mil. In some embodiments, the depth of the rib is 30 mil to 40 mil.

In some embodiments, the depth of the rib is 1 mil to 30 mil. In some embodiments, the depth of the rib is 2 mil to 30 mil. In some embodiments, the depth of the rib is 3 mil to 30 mil. In some embodiments, the depth of the rib is 4 mil to 30 mil. In some embodiments, the depth of the rib is 5 mil to 30 mil. In some embodiments, the depth of the rib is 6 mil to 30 mil. In some embodiments, the depth of the rib is 7 mil to 30 mil. In some embodiments, the depth of the rib is 8 mil to 30 mil. In some embodiments, the depth of the rib is 9 mil to 30 mil. In some embodiments, the depth of the rib is 10 mil to 30 mil. In some embodiments, the depth of the rib is 15 mil to 30 mil. In some embodiments, the depth of the rib is 20 mil to 30 mil.

In some embodiments, the depth of the rib is 1 mil to 20 mil. In some embodiments, the depth of the rib is 2 mil to 20 mil. In some embodiments, the depth of the rib is 3 mil to 20 mil. In some embodiments, the depth of the rib is 4 mil to 20 mil. In some embodiments, the depth of the rib is 5 mil to 20 mil. In some embodiments, the depth of the rib is 6 mil to 20 mil. In some embodiments, the depth of the rib is 7 mil to 20 mil. In some embodiments, the depth of the rib is 8 mil to 20 mil. In some embodiments, the depth of the rib is 9 mil to 20 mil. In some embodiments, the depth of the rib is 10 mil to 20 mil. In some embodiments, the depth of the rib is 15 mil to 20 mil.

In some embodiments, the depth of the rib is 1 mil to 15 mil. In some embodiments, the depth of the rib is 2 mil to 15 mil. In some embodiments, the depth of the rib is 3 mil to 15 mil. In some embodiments, the depth of the rib is 4 mil to 15 mil. In some embodiments, the depth of the rib is 5 mil to 15 mil. In some embodiments, the depth of the rib is 6 mil to 15 mil. In some embodiments, the depth of the rib is 7 mil to 15 mil. In some embodiments, the depth of the rib is 8 mil to 15 mil. In some embodiments, the depth of the rib is 9 mil to 15 mil. In some embodiments, the depth of the rib is 10 mil to 15 mil.

In some embodiments, the depth of the rib is 1 mil to 10 mil. In some embodiments, the depth of the rib is 2 mil to 10 mil. In some embodiments, the depth of the rib is 3 mil to 10 mil. In some embodiments, the depth of the rib is 4 mil to 10 mil. In some embodiments, the depth of the rib is 5 mil to 10 mil. In some embodiments, the depth of the rib is 6 mil to 10 mil. In some embodiments, the depth of the rib is 7 mil to 10 mil. In some embodiments, the depth of the rib is 8 mil to 10 mil. In some embodiments, the depth of the rib is 9 mil to 10 mil.

In some embodiments, the depth of the rib is 1 mil to 9 mil. In some embodiments, the depth of the rib is 2 mil to 9 mil. In some embodiments, the depth of the rib is 3 mil to 9 mil. In some embodiments, the depth of the rib is 4 mil to 9 mil. In some embodiments, the depth of the rib is 5 mil to 9 mil. In some embodiments, the depth of the rib is 6 mil to 9 mil. In some embodiments, the depth of the rib is 7 mil to 9 mil. In some embodiments, the depth of the rib is 8 mil to 9 mil. In some embodiments, the depth of the rib is 1 mil to 8 mil. In some embodiments, the depth of the rib is 2 mil to 8 mil. In some embodiments, the depth of the rib is 3 mil to 8 mil. In some embodiments, the depth of the rib is 4 mil to 8 mil. In some embodiments, the depth of the rib is 5 mil to 8 mil. In some embodiments, the depth of the rib is 6 mil to 8 mil. In some embodiments, the depth of the rib is 7 mil to 8 mil. In some embodiments, the depth of the rib is 1 mil to 7 mil. In some embodiments, the depth of the rib is 2 mil to 7 mil. In some embodiments, the depth of the rib is 3 mil to 7 mil. In some embodiments, the depth of the rib is 4 mil to 7 mil. In some embodiments, the depth of the rib is 5 mil to 7 mil. In some embodiments, the depth of the rib is 6 mil to 7 mil.

In some embodiments, the depth of the rib is 1 mil to 6 mil. In some embodiments, the depth of the rib is 2 mil to 6 mil. In some embodiments, the depth of the rib is 3 mil to 6 mil. In some embodiments, the depth of the rib is 4 mil to 6 mil. In some embodiments, the depth of the rib is 5 mil to 6 mil. In some embodiments, the depth of the rib is 1 mil to 5 mil. In some embodiments, the depth of the rib is 2 mil to 5 mil. In some embodiments, the depth of the rib is 3 mil to 5 mil. In some embodiments, the depth of the rib is 4 mil to 5 mil. In some embodiments, the depth of the rib is 1 mil to 4 mil. In some embodiments, the depth of the rib is 2 mil to 4 mil. In some embodiments, the depth of the rib is 3 mil to 4 mil. In some embodiments, the depth of the rib is 1 mil to 3 mil. In some embodiments, the depth of the rib is 2 mil to 3 mil. In some embodiments, the depth of the rib is 1 mil to 2 mil.

In some embodiments, a width of the rib is 1 mm. In some embodiments, the width of the rib is 2 mm. In some embodiments, the width of the rib is 3 mm. In some embodiments, the width of the rib is 4 mm. In some embodiments, the width of the rib is 5 mm. In some embodiments, the width of the rib is 6 mm. In some embodiments, the width of the rib is 7 mm. In some embodiments, the width of the rib is 8 mm. In some embodiments, the width of the rib is 9 mm. In some embodiments, the width of the rib is 10 mm. In some embodiments, the width of the rib is 15 mm. In some embodiments, the width of the rib is 20 mm. In some embodiments, the width of the rib is 30 mm. In some embodiments, the width of the rib is 40 mm. In some embodiments, the width of the rib is 50 mm.

In some embodiments, the width of the rib is more than 1 mm. In some embodiments, the width of the rib is more than 2 mm. In some embodiments, the width of the rib is more than 3 mm. In some embodiments, the width of the rib is more than 4 mm. In some embodiments, the width of the rib is more than 5 mm. In some embodiments, the width of the rib is more than 6 mm. In some embodiments, the width of the rib is more than 7 mm. In some embodiments, the width of the rib is more than 8 mm. In some embodiments, the width of the rib is more than 9 mm. In some embodiments, the width of the rib is more than 10 mm. In some embodiments, the width of the rib is more than 15 mm. In some embodiments, the width of the rib is more than 20 mm. In some embodiments, the width of the rib is more than 30 mm. In some embodiments, the width of the rib is more than 40 mm. In some embodiments, the width of the rib is more than 50 mm.

In some embodiments, the width of the rib is less than 1 mm. In some embodiments, the width of the rib is less than 2 mm. In some embodiments, the width of the rib is less than 3 mm. In some embodiments, the width of the rib is less than 4 mm. In some embodiments, the width of the rib is less than 5 mm. In some embodiments, the width of the rib is less than 6 mm. In some embodiments, the width of the rib is less than 7 mm. In some embodiments, the width of the rib is less than 8 mm. In some embodiments, the width of the rib is less than 9 mm. In some embodiments, the width of the rib is less than 10 mm. In some embodiments, the width of the rib is less than 15 mm. In some embodiments, the width of the rib is less than 20 mm. In some embodiments, the width of the rib is less than 30 mm. In some embodiments, the width of the rib is less than 40 mm. In some embodiments, the width of the rib is less than 50 mm.

In some embodiments, the width of the rib is 1 mm to 50 mm. In some embodiments, the width of the rib is 2 mm to 50 mm. In some embodiments, the width of the rib is 3 mm to 50 mm. In some embodiments, the width of the rib is 4 mm to 50 mm. In some embodiments, the width of the rib is 5 mm to 50 mm. In some embodiments, the width of the rib is 6 mm to 50 mm. In some embodiments, the width of the rib is 7 mm to 50 mm. In some embodiments, the width of the rib is 8 mm to 50 mm. In some embodiments, the width of the rib is 9 mm to 50 mm. In some embodiments, the width of the rib is 10 mm to 50 mm. In some embodiments, the width of the rib is 15 mm to 50 mm. In some embodiments, the width of the rib is 20 mm to 50 mm. In some embodiments, the width of the rib is 30 mm to 50 mm. In some embodiments, the width of the rib is 40 mm to 50 mm.

In some embodiments, the width of the rib is 1 mm to 40 mm. In some embodiments, the width of the rib is 2 mm to 40 mm. In some embodiments, the width of the rib is 3 mm to 40 mm. In some embodiments, the width of the rib is 4 mm to 40 mm. In some embodiments, the width of the rib is 5 mm to 40 mm. In some embodiments, the width of the rib is 6 mm to 40 mm. In some embodiments, the width of the rib is 7 mm to 40 mm. In some embodiments, the width of the rib is 8 mm to 40 mm. In some embodiments, the width of the rib is 9 mm to 40 mm. In some embodiments, the width of the rib is 10 mm to 40 mm. In some embodiments, the width of the rib is 15 mm to 40 mm. In some embodiments, the width of the rib is 20 mm to 40 mm. In some embodiments, the width of the rib is 30 mm to 40 mm.

In some embodiments, the width of the rib is 1 mm to 30 mm. In some embodiments, the width of the rib is 2 mm to 30 mm. In some embodiments, the width of the rib is 3 mm to 30 mm. In some embodiments, the width of the rib is 4 mm to 30 mm. In some embodiments, the width of the rib is 5 mm to 30 mm. In some embodiments, the width of the rib is 6 mm to 30 mm. In some embodiments, the width of the rib is 7 mm to 30 mm. In some embodiments, the width of the rib is 8 mm to 30 mm. In some embodiments, the width of the rib is 9 mm to 30 mm. In some embodiments, the width of the rib is 10 mm to 30 mm. In some embodiments, the width of the rib is 15 mm to 30 mm. In some embodiments, the width of the rib is 20 mm to 30 mm.

In some embodiments, the width of the rib is 1 mm to 20 mm. In some embodiments, the width of the rib is 2 mm to 20 mm. In some embodiments, the width of the rib is 3 mm to 20 mm. In some embodiments, the width of the rib is 4 mm to 20 mm. In some embodiments, the width of the rib is 5 mm to 20 mm. In some embodiments, the width of the rib is 6 mm to 20 mm. In some embodiments, the width of the rib is 7 mm to 20 mm. In some embodiments, the width of the rib is 8 mm to 20 mm. In some embodiments, the width of the rib is 9 mm to 20 mm. In some embodiments, the width of the rib is 10 mm to 20 mm. In some embodiments, the width of the rib is 15 mm to 20 mm.

In some embodiments, the width of the rib is 1 mm to 15 mm. In some embodiments, the width of the rib is 2 mm to 15 mm. In some embodiments, the width of the rib is 3 mm to 15 mm. In some embodiments, the width of the rib is 4 mm to 15 mm. In some embodiments, the width of the rib is 5 mm to 15 mm. In some embodiments, the width of the rib is 6 mm to 15 mm. In some embodiments, the width of the rib is 7 mm to 15 mm. In some embodiments, the width of the rib is 8 mm to 15 mm. In some embodiments, the width of the rib is 9 mm to 15 mm. In some embodiments, the width of the rib is 10 mm to 15 mm.

In some embodiments, the width of the rib is 1 mm to 10 mm. In some embodiments, the width of the rib is 2 mm to 10 mm. In some embodiments, the width of the rib is 3 mm to 10 mm. In some embodiments, the width of the rib is 4 mm to 10 mm. In some embodiments, the width of the rib is 5 mm to 10 mm. In some embodiments, the width of the rib is 6 mm to 10 mm. In some embodiments, the width of the rib is 7 mm to 10 mm. In some embodiments, the width of the rib is 8 mm to 10 mm. In some embodiments, the width of the rib is 9 mm to 10 mm.

In some embodiments, the width of the rib is 1 mm to 9 mm. In some embodiments, the width of the rib is 2 mm to 9 mm. In some embodiments, the width of the rib is 3 mm to 9 mm. In some embodiments, the width of the rib is 4 mm to 9 mm. In some embodiments, the width of the rib is 5 mm to 9 mm. In some embodiments, the width of the rib is 6 mm to 9 mm. In some embodiments, the width of the rib is 7 mm to 9 mm. In some embodiments, the width of the rib is 8 mm to 9 mm.

In some embodiments, the width of the rib is 1 mm to 8 mm. In some embodiments, the width of the rib is 2 mm to 8 mm. In some embodiments, the width of the rib is 3 mm to 8 mm. In some embodiments, the width of the rib is 4 mm to 8 mm. In some embodiments, the width of the rib is 5 mm to 8 mm. In some embodiments, the width of the rib is 6 mm to 8 mm. In some embodiments, the width of the rib is 7 mm to 8 mm.

In some embodiments, the width of the rib is 1 mm to 7 mm. In some embodiments, the width of the rib is 2 mm to 7 mm. In some embodiments, the width of the rib is 3 mm to 7 mm. In some embodiments, the width of the rib is 4 mm to 7 mm. In some embodiments, the width of the rib is 5 mm to 7 mm. In some embodiments, the width of the rib is 6 mm to 7 mm. In some embodiments, the width of the rib is 1 mm to 6 mm. In some embodiments, the width of the rib is 2 mm to 6 mm. In some embodiments, the width of the rib is 3 mm to 6 mm. In some embodiments, the width of the rib is 4 mm to 6 mm. In some embodiments, the width of the rib is 5 mm to 6 mm. In some embodiments, the width of the rib is 1 mm to 5 mm. In some embodiments, the width of the rib is 2 mm to 5 mm. In some embodiments, the width of the rib is 3 mm to 5 mm. In some embodiments, the width of the rib is 4 mm to 5 mm.

In some embodiments, the width of the rib is 1 mm to 4 mm. In some embodiments, the width of the rib is 2 mm to 4 mm. In some embodiments, the width of the rib is 3 mm to 4 mm. In some embodiments, the width of the rib is 1 mm to 3 mm. In some embodiments, the width of the rib is 2 mm to 3 mm. In some embodiments, the width of the rib is 1 mm to 2 mm.

In some embodiments, a spacing between two adjacent ribs on the backsheet is 1 mm. In some embodiments, the spacing is 2 mm. In some embodiments, the spacing is 3 mm. In some embodiments, the spacing is 4 mm. In some embodiments, the spacing is 5 mm. In some embodiments, the spacing is 6 mm. In some embodiments, the spacing is 7 mm. In some embodiments, the spacing is 8 mm. In some embodiments, the spacing is 9 mm. In some embodiments, the spacing is 10 mm. In some embodiments, the spacing is 15 mm. In some embodiments, the spacing is 20 mm. In some embodiments, the spacing is 30 mm. In some embodiments, the spacing is 40 mm. In some embodiments, the spacing is 50 mm.

In some embodiments, the spacing is more than 1 mm. In some embodiments, the spacing is more than 2 mm. In some embodiments, the spacing is more than 3 mm. In some embodiments, the spacing is more than 4 mm. In some embodiments, the spacing is more than 5 mm. In some embodiments, the spacing is more than 6 mm. In some embodiments, the spacing is more than 7 mm. In some embodiments, the spacing is more than 8 mm. In some embodiments, the spacing is more than 9 mm. In some embodiments, the spacing is more than 10 mm. In some embodiments, the spacing is more than 15 mm. In some embodiments, the spacing is more than 20 mm. In some embodiments, the spacing is more than 30 mm. In some embodiments, the spacing is more than 40 mm. In some embodiments, the spacing is more than 50 mm.

In some embodiments, the spacing is less than 1 mm. In some embodiments, the spacing is less than 2 mm. In some embodiments, the spacing is less than 3 mm. In some embodiments, the spacing is less than 4 mm. In some embodiments, the spacing is less than 5 mm. In some embodiments, the spacing is less than 6 mm. In some embodiments, the spacing is less than 7 mm. In some embodiments, the spacing is less than 8 mm. In some embodiments, the spacing is less than 9 mm. In some embodiments, the spacing is less than 10 mm. In some embodiments, the spacing is less than 15 mm. In some embodiments, the spacing is less than 20 mm. In some embodiments, the spacing is less than 30 mm. In some embodiments, the spacing is less than 40 mm. In some embodiments, the spacing is less than 50 mm.

In some embodiments, the spacing is 1 mm to 50 mm. In some embodiments, the spacing is 2 mm to 50 mm. In some embodiments, the spacing is 3 mm to 50 mm. In some embodiments, the spacing is 4 mm to 50 mm. In some embodiments, the spacing is 5 mm to 50 mm. In some embodiments, the spacing is 6 mm to 50 mm. In some embodiments, the spacing is 7 mm to 50 mm. In some embodiments, the spacing is 8 mm to 50 mm. In some embodiments, the spacing is 9 mm to 50 mm. In some embodiments, the spacing is 10 mm to 50 mm. In some embodiments, the spacing is 15 mm to 50 mm. In some embodiments, the spacing is 20 mm to 50 mm. In some embodiments, the spacing is 30 mm to 50 mm. In some embodiments, the spacing is 40 mm to 50 mm.

In some embodiments, the spacing is 1 mm to 40 mm. In some embodiments, the spacing is 2 mm to 40 mm. In some embodiments, the spacing is 3 mm to 40 mm. In some embodiments, the spacing is 4 mm to 40 mm. In some embodiments, the spacing is 5 mm to 40 mm. In some embodiments, the spacing is 6 mm to 40 mm. In some embodiments, the spacing is 7 mm to 40 mm. In some embodiments, the spacing is 8 mm to 40 mm. In some embodiments, the spacing is 9 mm to 40 mm. In some embodiments, the spacing is 10 mm to 40 mm. In some embodiments, the spacing is 15 mm to 40 mm. In some embodiments, the spacing is 20 mm to 40 mm. In some embodiments, the spacing is 30 mm to 40 mm.

In some embodiments, the spacing is 1 mm to 30 mm. In some embodiments, the spacing is 2 mm to 30 mm. In some embodiments, the spacing is 3 mm to 30 mm. In some embodiments, the spacing is 4 mm to 30 mm. In some embodiments, the spacing is 5 mm to 30 mm. In some embodiments, the spacing is 6 mm to 30 mm. In some embodiments, the spacing is 7 mm to 30 mm. In some embodiments, the spacing is 8 mm to 30 mm. In some embodiments, the spacing is 9 mm to 30 mm. In some embodiments, the spacing is 10 mm to 30 mm. In some embodiments, the spacing is 15 mm to 30 mm. In some embodiments, the spacing is 20 mm to 30 mm.

In some embodiments, the spacing is 1 mm to 20 mm. In some embodiments, the spacing is 2 mm to 20 mm. In some embodiments, the spacing is 3 mm to 20 mm. In some embodiments, the spacing is 4 mm to 20 mm. In some embodiments, the spacing is 5 mm to 20 mm. In some embodiments, the spacing is 6 mm to 20 mm. In some embodiments, the spacing is 7 mm to 20 mm. In some embodiments, the spacing is 8 mm to 20 mm. In some embodiments, the spacing is 9 mm to 20 mm. In some embodiments, the spacing is 10 mm to 20 mm. In some embodiments, the spacing is 15 mm to 20 mm.

In some embodiments, the spacing is 1 mm to 15 mm. In some embodiments, the spacing is 2 mm to 15 mm. In some embodiments, the spacing is 3 mm to 15 mm. In some embodiments, the spacing is 4 mm to 15 mm. In some embodiments, the spacing is 5 mm to 15 mm. In some embodiments, the spacing is 6 mm to 15 mm. In some embodiments, the spacing is 7 mm to 15 mm. In some embodiments, the spacing is 8 mm to 15 mm. In some embodiments, the spacing is 9 mm to 15 mm. In some embodiments, the spacing is 10 mm to 15 mm.

In some embodiments, the spacing is 1 mm to 10 mm. In some embodiments, the spacing is 2 mm to 10 mm. In some embodiments, the spacing is 3 mm to 10 mm. In some embodiments, the spacing is 4 mm to 10 mm. In some embodiments, the spacing is 5 mm to 10 mm. In some embodiments, the spacing is 6 mm to 10 mm. In some embodiments, the spacing is 7 mm to 10 mm. In some embodiments, the spacing is 8 mm to 10 mm. In some embodiments, the spacing is 9 mm to 10 mm.

In some embodiments, the spacing is 1 mm to 9 mm. In some embodiments, the spacing is 2 mm to 9 mm. In some embodiments, the spacing is 3 mm to 9 mm. In some embodiments, the spacing is 4 mm to 9 mm. In some embodiments, the spacing is 5 mm to 9 mm. In some embodiments, the spacing is 6 mm to 9 mm. In some embodiments, the spacing is 7 mm to 9 mm. In some embodiments, the spacing is 8 mm to 9 mm.

In some embodiments, the spacing is 1 mm to 8 mm. In some embodiments, the spacing is 2 mm to 8 mm. In some embodiments, the spacing is 3 mm to 8 mm. In some embodiments, the spacing is 4 mm to 8 mm. In some embodiments, the spacing is 5 mm to 8 mm. In some embodiments, the spacing is 6 mm to 8 mm. In some embodiments, the spacing is 7 mm to 8 mm.

In some embodiments, the spacing is 1 mm to 7 mm. In some embodiments, the spacing is 2 mm to 7 mm. In some embodiments, the spacing is 3 mm to 7 mm. In some embodiments, the spacing is 4 mm to 7 mm. In some embodiments, the spacing is 5 mm to 7 mm. In some embodiments, the spacing is 6 mm to 7 mm.

In some embodiments, the spacing is 1 mm to 6 mm. In some embodiments, the spacing is 2 mm to 6 mm. In some embodiments, the spacing is 3 mm to 6 mm. In some embodiments, the spacing is 4 mm to 6 mm. In some embodiments, the spacing is 5 mm to 6 mm. In some embodiments, the spacing is 1 mm to 5 mm. In some embodiments, the spacing is 2 mm to 5 mm. In some embodiments, the spacing is 3 mm to 5 mm. In some embodiments, the spacing is 4 mm to 5 mm. In some embodiments, the spacing is 1 mm to 4 mm. In some embodiments, the spacing is 2 mm to 4 mm. In some embodiments, the spacing is 3 mm to 4 mm. In some embodiments, the spacing is 1 mm to 3 mm. In some embodiments, the spacing is 2 mm to 3 mm. In some embodiments, the spacing is 1 mm to 2 mm.

In some embodiments, one or more of the ribs extends along the major dimension of the photovoltaic module (e.g., along the longest dimension of the photovoltaic module). In some embodiments, all of the ribs extends along the major dimension of the photovoltaic module. In some embodiments, none of the ribs extend along the major dimension of the photovoltaic module. In some embodiments, one or more of the ribs extends along a minor dimension of the photovoltaic module (e.g., along a dimension perpendicular to the longest dimension of the photovoltaic module). In some embodiments, all of the ribs extends along the minor dimension of the photovoltaic module. In some embodiments, none of the ribs extend along the minor dimension of the photovoltaic module. In some embodiments, one or more of the ribs extends along the major dimension, and one or more of the ribs extend along the minor dimension. In some embodiments, one or more of the ribs extends in a different direction. In some embodiments, all of the ribs extends in a different direction. In some embodiments, none of the ribs extend in a different direction.

In some embodiments, the frontsheet includes at least one frontsheet layer. In some embodiments, the frontsheet includes a plurality of frontsheet layers. In some embodiments, the frontsheet includes a textured surface. In some embodiments, the textured surface mimics the appearance of a non-photovoltaic material included in the roofing system.

In some embodiments, the cavities are formed during extrusion of the backsheet. In some embodiments, the cavities are formed by a secondary process after formation of the backsheet, and/or formation of the first layer. In some embodiments, the cavities are fully open to the environment. In some embodiments, one or both ends of the cavities are closed, such as by sealing.

In some embodiments, the cavities are filled with the filler material during extrusion of the backsheet (e.g., by co-extrusion). In some embodiments, the cavities are filled with the filler material by a secondary process after formation of the backsheet.

In some embodiments, the ribs are formed during extrusion of the backsheet. In some embodiments, the ribs are formed by a secondary process after formation of the backsheet, and/or formation of the first layer.

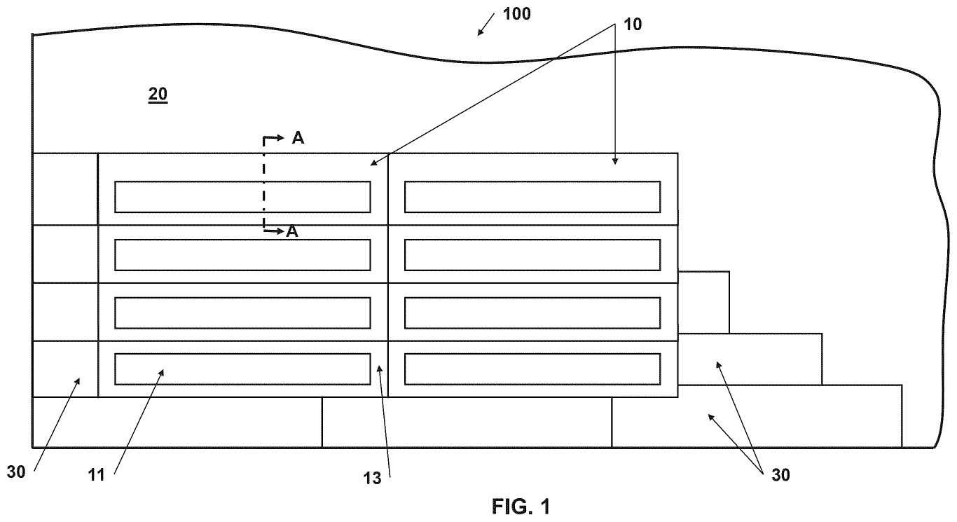

With reference to the drawings, FIG. 1 is a schematic top view of a partial installation of a roofing system, in accordance with some embodiments. As shown, in some embodiments, the roofing system 100 includes a plurality of photovoltaic modules 10 installed above a roof deck 20. In some embodiments, as FIG. 1 shows, each of the photovoltaic modules 10 includes at least one solar cell 11 positioned above backsheet 13. In some embodiments, the roofing system 100 includes a plurality of roofing materials 30 installed above the roof deck 20. In some embodiments, the roof deck 20 is a sloped roof deck. In some embodiments, the sloped roof deck is a steep slope roof deck. In some embodiments, one or more of the roofing system 100, the photovoltaic module 10, the roof deck 20, and/or the roofing material 30 are in accordance with the above discussions.

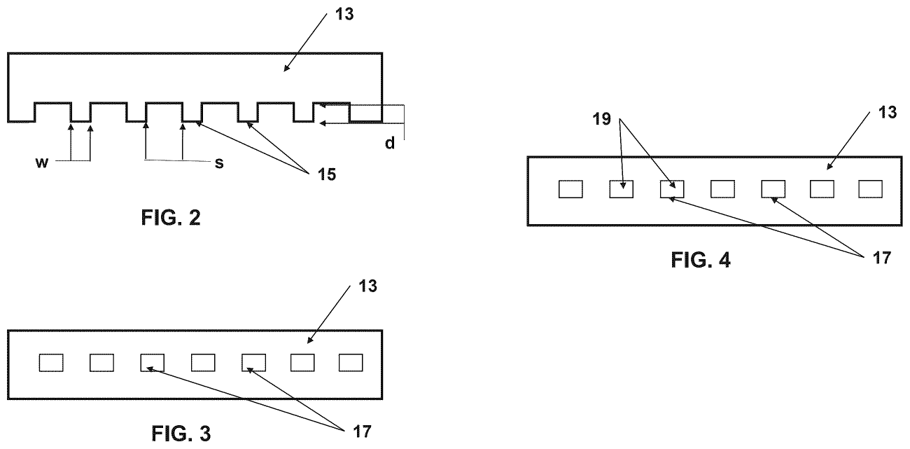

FIG. 2 is a schematic cross-sectional view of the backsheet 13 of one of the photovoltaic modules 10, taken along line A-A in FIG. 1, in accordance with some embodiments. As the figure shows, in some embodiments, the backsheet 13 includes a plurality of ribs 15. In some embodiments, the ribs 15 are in accordance with the above discussion. As the figure shows, in some embodiments, the ribs 15 having a depth “d,” and a width “w”; and are spaced apart from one another by a spacing “s.” In some embodiments, the depth “d” may be in accordance with the above description of the rib depth. In some embodiments, the width “w” may be in accordance with the above description of the rib width. In some embodiments, the spacing “s” may be in accordance with the above description of the rib spacing. It is to be understood that any reference to a depth of a rib may apply to a height of a rib.

FIG. 3 is a schematic cross-sectional view of the backsheet 13 of one of the photovoltaic modules 10, taken along line A-A in FIG. 1, in accordance with some embodiments. As the figure shows, in some embodiments, the backsheet 13 includes a plurality of cavities 17 (e.g., open-and/or closed-cells). In some embodiments, the cavities 17 are in accordance with the above discussion.

FIG. 4 is a schematic cross-sectional view of the backsheet 13 of one of the photovoltaic modules 10, taken along line A-A in FIG. 1, in accordance with some embodiments. As the figure shows, in some embodiments, the backsheet 13 includes a plurality of cavities 17 including a filler material 19. In some embodiments, the filler material 19 is in accordance with the above discussion.

In some embodiments, a roofing module includes at least one layer. In some embodiments, a roofing module includes a plurality of layers. In some embodiments, at least one of the layers of the roofing module includes one or more of the embodiments of the backsheet 13 disclosed herein. In some embodiments, the roofing module is a roofing shingle. In some embodiments, the roofing shingle is not electrically active. In some embodiments, the roofing shingle does not include a solar cell. In some embodiments, the roofing module includes a structure, composition, component, and/or function similar to those of one or more embodiments of roofing materials disclosed, shown, and/or described in either or both of U.S. application Ser. No. 17/831,307, filed Jun. 2, 2022, titled “Roofing Module System,” and published under U.S. Patent Application Publication No. 2022-0393637 on Dec. 8, 2022; and/or U.S. application Ser. No. 18/169,718, filed Feb. 15, 2023, titled “Roofing Module System,” and published under U.S. Patent Application Publication No. 2023-0203815 on Jun. 29, 2023; and/or U.S. application Ser. No. 18/352,894, filed Jul. 14, 2023, titled “Solar Roofing System with Fiber Composite Roofing Shingles,” and published under U.S. Patent Application Publication No. 2024-0018781 on Jan. 18, 2024, owned by GAF Energy LLC; the disclosures of each of the foregoing are incorporated by reference herein in their entireties, with certain different and/or additional features of one or more of the embodiments of the backsheet 13 disclosed herein.

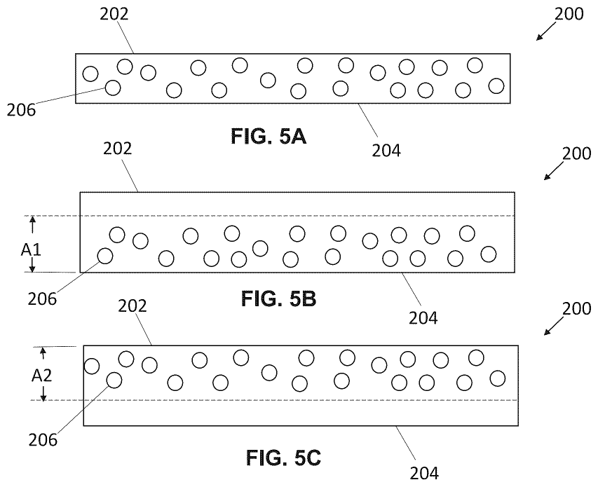

Referring to FIGS. 5A through 5C, in some embodiments, a backsheet 200 includes a first, upper surface 202, a second, lower surface 204 opposite the upper surface 202, and a plurality of pores 206 between the upper surface 202 and the lower surface 204. In some embodiments, at least some of the plurality of pores 206 are closed cell pores. In some embodiments, a substantial number of the plurality of pores 206 are closed cell pores. In some embodiments, all of the plurality of pores 206 are closed cell pores. In some embodiments, at least some of the plurality of pores 206 are open cell pores. In some embodiments, a substantial number of the plurality of pores 206 are open cell pores. In some embodiments, all of the plurality of pores 206 are open cell pores. In some embodiments, some of the plurality of pores 206 are open cell pores and some of the plurality of pores 206 are closed cell pores. In some embodiments, at least some of the plurality of pores 206 are open cell pores and a substantial number of the plurality of pores 206 are closed cell pores. In some embodiments, at least some of the plurality of pores 206 are closed cell pores and a substantial number of the plurality of pores 206 are open cell pores.

In some embodiments, as illustrated in FIG. 5A, an entirety of a volume of the backsheet 200 is porous and includes the plurality of pores 206. In some embodiments, the plurality of pores 206 are dispersed and located substantially between the upper surface 202 and the lower surface 204 of the backsheet 200. In some embodiments, the plurality of pores 206 are randomly dispersed and located between the upper surface 202 and the lower surface 204 of the backsheet 200.

In some embodiments, as illustrated in FIG. 5B, the plurality of pores 206 are located proximate to the lower surface 204 of the backsheet 200. In some embodiments, a substantial number of the plurality of pores 206 are located proximate to the lower surface 204 of the backsheet 200. In some embodiments, a substantial number of the plurality of pores 206 are located proximate to the lower surface 204 of the backsheet 200 within a volumetric area A1. In some embodiments, none of the plurality of pores 206 are located proximate to the upper surface 202 of the backsheet 200. In some embodiments, a minimal number of the plurality of pores 206 are located proximate to the upper surface 202 of the backsheet 200.

In some embodiments, as illustrated in FIG. 5C, the plurality of pores 206 are located proximate to the upper surface 202 of the backsheet 200. In some embodiments, a substantial number of the plurality of pores 206 are located proximate to the upper surface 202 of the backsheet 200. In some embodiments, a substantial number of the plurality of pores 206 are located proximate to the upper surface 202 of the backsheet 200 within a volumetric area A2. In some embodiments, none of the plurality of pores 206 are located proximate to the lower surface 204 of the backsheet 200. In some embodiments, a minimal number of the plurality of pores 206 are located proximate to the lower surface 204 of the backsheet 200.

In some embodiments, the pore density of the backsheet 200 is 0% to 75%. In some embodiments, the pore density of the backsheet 200 is 0% to 50%. In some embodiments, the pore density of the backsheet 200 is 0% to 25%. In some embodiments, the pore density of the backsheet 200 is 25% to 75%. In some embodiments, the pore density of the backsheet 200 is 50% to 75%. In some embodiments, the pore density of the backsheet 200 is 50% to 75%.

In some embodiments, the pore diameter of each, some or all of the plurality of pores 206 is 0.5 μm to 100 μm. In some embodiments, the pore diameter of each, some or all of the plurality of pores 206 is 0.5 μm to 75 μm. In some embodiments, the pore diameter of each, some or all of the plurality of pores 206 is 0.5 μm to 50 μm. In some embodiments, the pore diameter of each, some or all of the plurality of pores 206 is 0.5 μm to 25 μm. In some embodiments, the pore diameter of each, some or all of the plurality of pores 206 is 0.5 μm to 15 μm. In some embodiments, the pore diameter of each, some or all of the plurality of pores 206 is 0.5 μm to 10 μm. In some embodiments, the pore diameter of each, some or all of the plurality of pores 206 is 0.5 μm to 5 μm. In some embodiments, the pore diameter of each, some or all of the plurality of pores 206 is 0.5 μm to 1 μm.

In some embodiments, the pore diameter of each, some or all of the plurality of pores 206 is 1 μm to 100 μm. In some embodiments, the pore diameter of each, some or all of the plurality of pores 206 is 1 μm to 75 μm. In some embodiments, the pore diameter of each, some or all of the plurality of pores 206 is 1 μm to 50 μm. In some embodiments, the pore diameter of each, some or all of the plurality of pores 206 is 1 μm to 25 μm. In some embodiments, the pore diameter of each, some or all of the plurality of pores 206 is 1 μm to 15 μm. In some embodiments, the pore diameter of each, some or all of the plurality of pores 206 is 1 μm to 10 μm. In some embodiments, the pore diameter of each, some or all of the plurality of pores 206 is 1 μm to 5 μm.

In some embodiments, the pore diameter of each, some or all of the plurality of pores 206 is 5 μm to 100 μm. In some embodiments, the pore diameter of each, some or all of the plurality of pores 206 is 5 μm to 75 μm. In some embodiments, the pore diameter of each, some or all of the plurality of pores 206 is 5 μm to 50 μm. In some embodiments, the pore diameter of each, some or all of the plurality of pores 206 is 5 μm to 25 μm. In some embodiments, the pore diameter of each, some or all of the plurality of pores 206 is 5 μm to 15 μm. In some embodiments, the pore diameter of each, some or all of the plurality of pores 206 is 5 μm to 10 μm.

In some embodiments, the pore diameter of each, some or all of the plurality of pores 206 is 10 μm to 100 μm. In some embodiments, the pore diameter of each, some or all of the plurality of pores 206 is 10 μm to 75 μm. In some embodiments, the pore diameter of each, some or all of the plurality of pores 206 is 10 μm to 50 μm. In some embodiments, the pore diameter of each, some or all of the plurality of pores 206 is 10 μm to 25 μm. In some embodiments, the pore diameter of each, some or all of the plurality of pores 206 is 10 μm to 15 μm.

In some embodiments, the pore diameter of each, some or all of the plurality of pores 206 is 15 μm to 100 μm. In some embodiments, the pore diameter of each, some or all of the plurality of pores 206 is 15 μm to 75 μm. In some embodiments, the pore diameter of each, some or all of the plurality of pores 206 is 15 μm to 50 μm. In some embodiments, the pore diameter of each, some or all of the plurality of pores 206 is 15 μm to 25 μm. In some embodiments, the pore diameter of each, some or all of the plurality of pores 206 is 25 μm to 100 μm. In some embodiments, the pore diameter of each, some or all of the plurality of pores 206 is 25 μm to 75 μm. In some embodiments, the pore diameter of each, some or all of the plurality of pores 206 is 25 μm to 50 μm. In some embodiments, the pore diameter of each, some or all of the plurality of pores 206 is 50 μm to 100 μm. In some embodiments, the pore diameter of each, some or all of the plurality of pores 206 is 50 μm to 75 μm. In some embodiments, the pore diameter of each, some or all of the plurality of pores 206 is 75 μm to 100 μm.

In some embodiments, the pore diameter of each, some or all of the plurality of pores 206 is 0.5 μm. In some embodiments, the pore diameter of each, some or all of the plurality of pores 206 is 1 μm. In some embodiments, the pore diameter of each, some or all of the plurality of pores 206 is 5 μm. In some embodiments, the pore diameter of each, some or all of the plurality of pores 206 is 10 μm. In some embodiments, the pore diameter of each, some or all of the plurality of pores 206 is 15 μm. In some embodiments, the pore diameter of each, some or all of the plurality of pores 206 is 25 μm. In some embodiments, the pore diameter of each, some or all of the plurality of pores 206 is 50 μm. In some embodiments, the pore diameter of each, some or all of the plurality of pores 206 is 75 μm. In some embodiments, the pore diameter of each, some or all of the plurality of pores 206 is 100 μm.

In some embodiments, the backsheet 200 is composed of TPO. In some embodiments, the backsheet 200 is composed of foamed TPO. In some embodiments, the backsheet 200 includes at least one layer. In some embodiments, the backsheet 200 includes a plurality of layers. In some embodiments, at least one layer of the backsheet 200 is composed of foamed TPO. In some embodiments, more than one of the layers of the backsheet 200 is composed of foam TPO.

In some embodiments, a roofing module includes at least one layer. In some embodiments, a roofing module includes a plurality of layers. In some embodiments, at least one of the layers of the roofing module includes one or more of the embodiments of the backsheet 200 disclosed herein. In some embodiments, the roofing module is a roofing shingle. In some embodiments, the roofing shingle is not electrically active. In some embodiments, the roofing shingle does not include a solar cell. In some embodiments, the roofing module includes a structure, composition, component, and/or function similar to those of one or more embodiments of roofing materials disclosed, shown, and/or described in either or both of U.S. application Ser. No. 17/831,307, filed Jun. 2, 2022, titled “Roofing Module System,” and published under U.S. Patent Application Publication No. 2022-0393637 on Dec. 8, 2022; and/or U.S. application Ser. No. 18/169,718, filed Feb. 15, 2023, titled “Roofing Module System,” and published under U.S. Patent Application Publication No. 2023-0203815 on Jun. 29, 2023; and/or U.S. application Ser. No. 18/352,894, filed Jul. 14, 2023, titled “Solar Roofing System with Fiber Composite Roofing Shingles,” and published under U.S. Patent Application Publication No. 2024-0018781 on Jan. 18, 2024, owned by GAF Energy LLC; the disclosures of each of the foregoing are incorporated by reference herein in their entireties, with certain different and/or additional features of one or more of the embodiments of the backsheet 200 disclosed herein.

Variations, modifications, and alterations to embodiments of the present disclosure described above will make themselves apparent to those skilled in the art. All such variations, modifications, alterations and the like are intended to fall within the spirit and scope of the present disclosure, limited solely by the appended claims.

While several embodiments of the present disclosure have been described, it is understood that these embodiments are illustrative only, and not restrictive, and that many modifications may become apparent to those of ordinary skill in the art. For example, all dimensions discussed herein are provided as examples only, and are intended to be illustrative and not restrictive.

Any feature or element that is positively identified in this description may also be specifically excluded as a feature or element of an embodiment of the present as defined in the claims.

The disclosure described herein may be practiced in the absence of any element or elements, limitation or limitations, which is not specifically disclosed herein. The terms and expressions which have been employed are used as terms of description and not of limitation, and there is no intention in the use of such terms and expressions of excluding any equivalents of the features shown and described or portions thereof, but it is recognized that various modifications are possible within the scope of the disclosure.

What is claimed is:

1. A roofing system, comprising:
a roof deck; and
a plurality of photovoltaic modules installed on the roof deck,
wherein each of the plurality of photovoltaic modules includes
at least one solar cell,
an encapsulant encapsulating the at least one solar cell, and
a backsheet,
wherein the backsheet is below the encapsulant,
wherein the backsheet comprises a first layer, and
wherein the first layer comprises a plurality of cavities.

2. The roofing system of claim 1, wherein the plurality of cavities comprises at least one closed cavity.

3. The roofing system of claim 1, wherein the plurality of cavities comprises at least one open cavity.

4. The roofing system of claim 1, wherein each of the plurality of photovoltaic modules further comprises a filler material in at least one cavity of the plurality of cavities.

5. The roofing system of claim 4, wherein the filler material comprises a fire-retardant material.

6. The roofing system of claim 5, wherein the fire-retardant material comprises a liquid.

7. The roofing system of claim 4, wherein the filler material comprises a phase-change material.

8. The roofing system of claim 7, wherein the phase-change material comprises hydrated salts.

9. The roofing system of claim 8, wherein the hydrated salts comprises calcium or sodium.

10. The roofing system of claim 4, wherein the filler material comprises a gas.

11. The roofing system of claim 10, wherein the gas comprises air.

12. The roofing system of claim 10, wherein the gas comprises an inert gas.

13. The roofing system of claim 1, wherein the plurality of cavities comprises at least two channels extending between opposite ends of the first layer.

14. The roofing system of claim 13, wherein the at least two channels extend along a major dimension of the photovoltaic module.

15. A roofing system, comprising:
a roof deck; and
a plurality of photovoltaic modules installed above the roof deck,
wherein each of the plurality of photovoltaic modules includes
at least one solar cell,
an encapsulant encapsulating the at least one solar cell, and
a backsheet,
wherein the backsheet is below the encapsulant,
wherein the backsheet comprises a first layer, and
wherein the first layer comprises a plurality of ribs, and
wherein each of the ribs extend between opposite ends of the first layer.

16. The roofing system of claim 15, wherein the plurality of ribs comprises at least two ribs.

17. The roofing system of claim 15, wherein the plurality of ribs extends along a major dimension of the photovoltaic module.

18. A photovoltaic module, comprising:
at least one solar cell;
an encapsulant encapsulating the at least one solar cell; and
a backsheet,
wherein the backsheet is below the encapsulant,
wherein the backsheet comprises a first layer, and
wherein the first layer comprises a plurality of cavities.

19. The photovoltaic module of claim 18, wherein the plurality of cavities comprises at least one closed cavity.

20. The photovoltaic module of claim 18, wherein the plurality of cavities comprises at least one open cavity.
